(19) United States
(12) Patent Application Publication
(10) Pub. No.: US 2025/0105620 A1
(43) Pub. Date: Mar. 27, 2025

(54) LINE PROTECTION METHOD AND SYSTEM FOR WIND FARM CONNECTED TO FLEXIBLE DC SYSTEM

(71) Applicant: NORTH CHINA ELECTRIC POWER UNIVERSITY, Beijing (CN)

(72) Inventors: Jing MA, Beijing (CN); Xieyu LIN, Beijing (CN); Guojie XU, Beijing (CN); Zhuoer GAO, Beijing (CN)

(73) Assignee: NORTH CHINA ELECTRIC POWER UNIVERSITY, Beijing (CN)

(21) Appl. No.: 18/759,857

(22) Filed: Jun. 29, 2024

(30) Foreign Application Priority Data
Sep. 25, 2023 (CN) 202311244107.6

(51) Int. Cl. H02H 7/26; G01R 31/08; H02J 3/38

(52) U.S. Cl. CPC H02H 7/268; G01R 31/085; H02H 7/263; H02J 3/381; H02J 2300/28

(57) ABSTRACT

A line protection method and system for wind farm connected to flexible DC system involves: obtaining high frequency components of voltage and current at protection installations on both sides of a transmission line, when a fault of the transmission line of a direct drive wind field connected to a flexible DC system is monitored; obtaining 1-mode transient action impedance difference of the transmission line, based on the high-frequency components of voltage and current at the protection installations on both sides of the transmission line; determining whether a fault inside the area of the transmission line occurs, based on the 1-mode transient action impedance difference and fault identification criterion of the transmission line, and starting the protection action of the transmission line if it is determined that the fault inside the area of the transmission line occurs.

### CROSS-REFERENCE TO RELATED APPLICATIONS

The present disclosure claims priority to Chinese Patent Application No. 202311244107.6, filed on Sep. 25, 2023, which is hereby incorporated by reference in its entirety.

### TECHNICAL FIELD

This application relates to the field of power system relay protection technology, especially to a line protection method and system for wind farm connected to flexible DC system.

### BACKGROUND

In China, load center and wind energy resources are inversely distributed, and power must be absorbed by large-scale power transmission. The flexible DC transmission has the advantages of low cost, long distance and no traditional DC commutation failure, which makes it an effective way to solve the problem of unbalanced distribution of wind energy and load. If the large-scale wind power transmission line is not removed in time after the fault occurs, the long-term fault operation of the system will cause the accident to expand, so it must be removed quickly and reliably. Therefore, it is of great practical significance to study the protection method of the transmission line of the wind power connected to the flexible DC system for the safe operation of the actual system.

At present, according to the electrical characteristics when constructing the protection criterion, the existing line pilot protection is divided into: line pilot protection of power frequency and line pilot protection of transient quantity. The weak feed of wind farm and the wide application of power electronic equipment make the transient process of power system fault more complex and fast, so that the operating parameters such as voltage, frequency and current of power system no longer remain constant as in steady-state operation, but change greatly with time. Moreover, the phasor extraction of power frequency based on Fourier algorithm is no longer accurate, and the protection based on power frequency is no longer suitable for the transmission line of large-scale wind farm connected to flexible DC system.

Therefore, the line protection operation of the existing wind farm through the flexible DC transmission system is not reliable, and it is prone to protection misoperation and rejection.

### SUMMARY

In view of the above analysis, the embodiment of the application aims to provide a line protection method and system for the wind farm connected to the flexible DC system, which is used to solve the problem that the line protection operation of the existing wind farm through the flexible DC transmission system is not reliable, and the protection misoperation and rejection are easy to occur.

On one aspect, the embodiment of the application provides a line protection method for wind farm connected to flexible DC system, comprises the following steps:

When a fault occurs in the transmission line of the direct-drive wind farm connected to the flexible DC system, the high-frequency components of the voltage and current at the protection installations on both sides of the transmission line are obtained.

Based on the high-frequency components of voltage and current at the protection installations on both sides of the transmission line, the 1-mode transient action impedance difference of the transmission line is obtained.

Based on the 1-mode transient action impedance difference and fault identification criterion of the transmission line, whether the internal fault of the transmission line occurs is determined. If so, the protection action of the transmission line is started.

Further, the 1-mode transient action impedance difference of the transmission line is obtained by the following method:

Based on the high-frequency components of the voltage and current at the protection installations on both sides of the transmission line for each of the sampling points, the 1-mode high-frequency components of the voltage and current at the protection installations on both sides of the transmission line for each of the sampling points are obtained.

Based on the high-frequency components of the voltage and current at the protection installations on both sides of the transmission line at each sampling point, the 1-mode high-frequency components of the voltage and current at the protection installations on both sides of the transmission line at each sampling point are obtained.

Based on the 1-mode action impedance of the transmission line of all the sampling points in a sampling period after fault, the 1-mode transient action impedance difference of the transmission line is obtained.

Further, the 1-mode transient action impedance difference of the transmission line is expressed as:

$${S}_{act} ( {ω}_{f} ) = \frac{1}{H} {\sum }_{h = 1}^{H} {( {Z}_{act 1 , h} ( {ω}_{f} ) - {Z}_{L} ( {ω}_{f} ) )}^{2}$$

In the formula, S_{act}(ω_{f}) represents the 1-mode transient action impedance difference when the high-frequency is ω_{f}, H represents the total number of the sampling points in a sampling period after fault, Z_{act1,h}(ω_{f}) represents the 1-mode action impedance at the h-th sampling point when the high-frequency is ω_{f}, and Z_{L}(ω_{f}) represents the equivalent impedance of the transmission line when the high-frequency is ω_{f}.

Further, when the high-frequency of the h-th sampling point is ω_{f}, the 1-mode action impedance Z_{act1,h}(ω_{f}) is expressed as:

$${Z}_{act 1 , h} ( {ω}_{f} ) = \frac{{U}_{M 1 , h} ( {ω}_{f} )}{{I}_{M 1 , h} ( {ω}_{f} )} + \frac{{U}_{N 1 , h} ( {ω}_{f} )}{{I}_{N 1 , h} ( {ω}_{f} )}$$

In the formula, U_{M1,h}(ω_{f}) and I_{M1,h}(ω_{f}) respectively represent the 1-mode voltage high-frequency component and the 1-mode current high-frequency component of the h-th sampling point when the high-frequency is ω_{f} at the wind farm side protection installation of the transmission line, U_{N1,h}(ω_{f}) and I_{N1,h}(ω_{f}) respectively represent the 1-mode voltage high-frequency component and the 1-mode current high-frequency component of the h-th sampling point when the high-frequency is ω_{f} at the flexible DC side protection installation of the transmission line.

Furthermore, the fault identification criterion includes:

S_{act}(ω_{f})≥Sₛₑₜ(ω_{f})

In the formula, Sₛₑₜ(ω_{f}) represents the threshold value of the 1-mode transient action impedance difference of the transmission line when the high-frequency is ω_{f};

If S_{act}(ω_{f}) satisfies the fault identification criterion, it is judged to be a fault inside the area of the transmission line; otherwise, it is judged to be a fault outside the area of the transmission line.

Further, when the high-frequency is ω_{f}, the threshold value Sₛₑₜ(ω_{f}) of the 1-mode transient action impedance difference of the transmission line satisfies the following formula:

S_{actmin}^{out}(ω_{f})<Sₛₑₜ(ω_{f})<S_{actmax}ⁱⁿ(ω_{f})

In the formula, S_{actmax}ⁱⁿ(ω_{f}) represents the maximum value of fault inside the area of the transmission line when the high-frequency is ω_{f}, and S_{actmin}^{out}(ω_{f}) represents the minimum value of fault outside the area of the transmission line when the high-frequency is ω_{f}.

Further, the maximum fault S_{actmax}ⁱⁿ(ω_{f}) in the transmission line area when the high-frequency is ω_{f} is expressed as:

$${S}_{actmax}^{i n} ( {ω}_{f} ) = {( {Z}_{f c} ( {ω}_{f} ) + {z}_{mmc 1} ( {ω}_{f} ) + {z}_{L} ( {ω}_{f} ) - {Z}_{f c} ( {ω}_{f} ) \frac{{i}_{fc 1} ( {ω}_{f} )}{{i}_{M 1} ( {ω}_{f} )} - \frac{{u}_{mmc 1} ( {ω}_{f} )}{{i}_{N 1} ( {a}_{f} )} )}^{2}$$

In the formula, z_{fc}(ω_{f}) represents the equivalent impedance of the wind field side at the high-frequency of ω_{f}, z_{mmc1}(ω_{f}) represents the 1-mode equivalent impedance of the flexible DC side at the high-frequency of ω_{f}, i_{fc1}(ω_{f}) represents the 1-mode equivalent transient current source of the wind field side at the high-frequency of ω_{f}, u_{mmc1}(ω_{f}) represents the 1-mode transient voltage source of the flexible side at the high-frequency of (ω_{f}, i_{M1}(ω_{f}) represents the 1-mode current high frequency component of the wind field side of the transmission line at protection installations at any sampling time when the high-frequency is ω_{f}, i_{N1}(ω_{f}) represents the 1-mode current high frequency component of the flexible DC side of the transmission line at protection installation at any sampling time when the high-frequency is ω_{f};

The minimum value S_{actmin}^{out}(ω_{f}) of the fault inside the area of the transmission line when the high-frequency is ω_{f} is expressed as:

S_{actmin}^{out}(ω_{f})=Z_{L}²(ω_{f}).

Further, the high-frequency ω_{f} is taken as ωₘₐₓ; it is to determine ωₘₐₓ by the following way:

$${ω}_{R} = max \{ {ω}_{1} , {ω}_{2} , … , {ω}_{6} \}$$

In the formula, ω₁˜ω₆ are the frequency solutions of the derivative of the 1-mode action impedance difference of the transmission line equal to 0, respectively, and max{ }represents the maximum value.

Further, the 1-mode action impedance difference ΔZ_{act1}(ω_{f}) of the transmission line is expressed as:

$${ΔZ}_{act 1} ( {ω}_{f} ) = \frac{{A}_{7} {ω}_{f}^{7} + {A}_{5} {ω}_{f}^{5} + {A}_{3} {ω}_{f}^{3} + {A}_{1} {ω}_{f}}{{B}_{6} {ω}_{f}^{6} + {B}_{4} {ω}_{f}^{4} + {B}_{2} {ω}_{f}^{2} + {B}_{0}}$$

In the formula, A₇, A₅, A₃, A₁, B₆, B₄, B₂, B₀ are constants calculated according to the fault transient model on both sides of the transmission line.

On another aspect, the embodiment of the application provides a line protection system for a wind farm connected to a flexible DC system, comprises:

The data acquisition module, which is used to obtain the high-frequency components of voltage and current at the protection installations on both sides of the transmission line when the fault of the transmission line of the direct-drive wind field connected to the flexible DC system is monitored.

The 1-mode transient action impedance difference acquisition module, which is used to obtain the 1-mode transient action impedance difference of the transmission line based on the high-frequency components of the voltage and current at the protection installations on both sides of the transmission line.

The fault identification and protection startup module, which is used to determine whether a fault inside the area of the transmission line occurs based on the 1-mode transient action impedance difference and the fault identification criterion of the transmission line. If so, the protection action of the transmission line is started.

Compared with the existing technology, the application can achieve the following beneficial effects:

The line protection method and system based on wind field connected to flexible DC system proposed in this application can calculate the 1-mode transient action impedance difference at the protection installation of the transmission line based on the data collected after fault, and accurately identify the faults inside and outside the area of the transmission line according to the fault identification criterion. It has fast action speed; is not affected by transition resistance, fault location and fault type; has high sensitivity, and has low sampling frequency. It is easy to implement in engineering, and fundamentally eliminates the problem of fault misoperation and rejection of transmission line.

In this application, the above technical schemes can also be combined with each other to realize more optimal combination schemes. Other characteristics and advantages of the present application will be described in a subsequent specification, and some of the advantages may become apparent from the specification or may be understood through the implementation of the present application. The purpose and other advantages of the application may be realized and obtained through the contents specifically indicated in the specification and the appended drawings.

### BRIEF DESCRIPTION OF DRAWINGS

The appended drawings are used only for the purpose of showing specific embodiments and are not considered to be a limitation of the present application. Throughout the appended drawings, the same reference symbols represent the same components.

FIG. 1 is the flow diagram of the line protection method of the wind farm connected to the flexible DC system provided by embodiment 1 of the application.

FIG. 2 is the schematic diagram of the transmission line of the wind farm connected to the flexible DC system provided by the embodiment 1 of the application;

FIG. 3 is a diagram of the grid-connected system of the direct-drive wind farm provided by the embodiment 1 of the application;

FIG. 4 shows the topology and control block diagram of the grid-side converter of the direct-drive wind turbine provided by the embodiment 1 of the application;

FIG. 5 is a control block diagram of the phase-locked loop of the direct-drive wind turbine provided by the embodiment 1 of the application;

FIG. 6 is the fault transient network of the direct-drive wind farm station provided by the embodiment 1 of the application;

FIG. 7 is the fault transient model of the direct-drive wind farm provided by the embodiment 1 of the application;

FIG. 8 is the topology diagram of MMC converter station provided by embodiment 1 of the application;

FIG. 9 is the fault transient model of flexible DC system provided by the embodiment 1 of the application;

FIG. 10 is the fault transient network in the transmission line area provided by the embodiment 1 of the application;

FIG. 11 is the fault transient network of the wind field side outside the area of the transmission line provided by the embodiment 1 of the application;

FIG. 12 is the fault transient network of the flexible DC side outside the area of the transmission line provided by the embodiment 1 of the application;

FIG. 13 is a schematic diagram of the structure of the line protection system of the wind farm connected to the flexible DC system provided by embodiment 2 of the application;

FIG. 14A shows the S_{act} of different transition resistance A phase grounding faults inside the area of the transmission line provided by the embodiment 3 of the application;

FIG. 14B shows the S_{act} of the interphase fault with different transition resistance AB inside the area of the transmission line provided by the embodiment 3 of the application;

FIG. 14C shows the S_{act} of the three-phase fault of different transition resistance ABC inside the area of the transmission line provided by the embodiment 3 of the application;

FIG. 15A shows the S_{act} of phase A grounding fault at different positions inside the area of the transmission line provided by the embodiment 3 of the application;

FIG. 15B shows the S_{act} of AB two-phase interphase fault at different positions inside the area of the transmission line provided by the embodiment 3 of the application;

FIG. 16A shows the S_{act} of AC two-phase interphase fault on the wind field side outside the area of the transmission line provided by the embodiment 3 of the application;

FIG. 16B shows the S_{act} of the ABC three-phase fault on the wind field side outside the area of the transmission line provided by the embodiment 3 of the application;

FIG. 17A shows the S_{act} when the A-phase grounding fault occurs on the flexible DC side outside the area of the transmission line provided by the embodiment 3 of the application;

FIG. 17B shows the S_{act} when ABC three-phase fault occurs on the flexible DC side outside the area of the transmission line provided by the embodiment 3 of the application.

### DETAILED DESCRIPTION

The proposed method is described in detail below in conjunction with the diagrams in the appendix. It should be emphasized that the following description is only exemplary and is not intended to limit the scope of this application.

### Embodiment 1

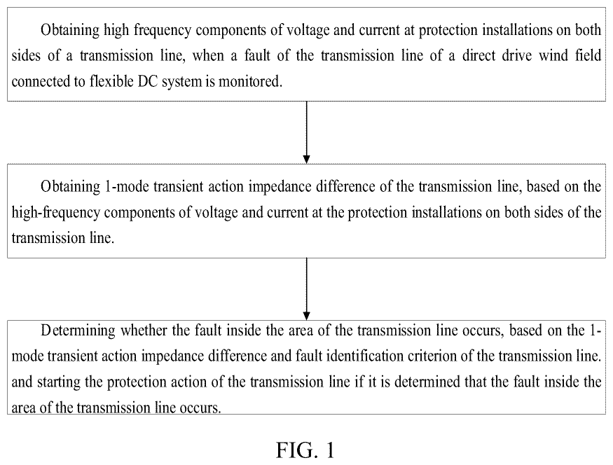

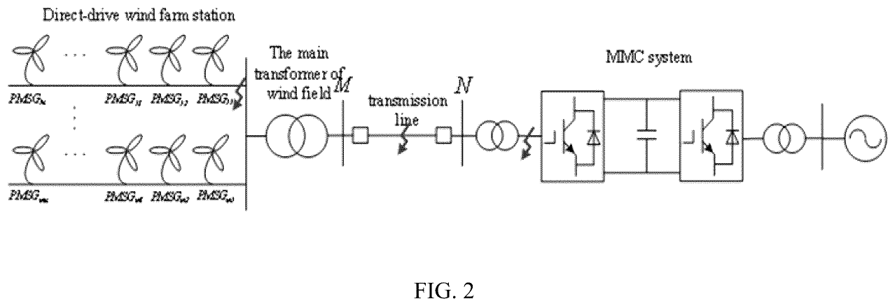

A specific embodiment of the application discloses a line protection method for a wind farm connected to flexible DC system, as shown in FIG. 1, including the following steps:

S1. When the fault of the transmission line of the direct-drive wind farm connected to the flexible DC system is monitored, the high-frequency components of the voltage and current at the protection installations on both sides of the transmission line are obtained.

Specifically, the current and voltage are collected by the transformers at the protection installations on both sides of the transmission line, and the high-frequency components of the voltage and current are extracted through the existing technology.

S2, based on the high-frequency components of voltage and current at the protection installations on both sides of the transmission line, the 1-mode transient action impedance difference of the transmission line is obtained.

In the implementation, the 1-mode transient action impedance difference of the transmission line is obtained by the following steps:

S21, based on the high-frequency components of the voltage and current at the protection installations on both sides of the transmission line for each of the sampling points, the 1-mode high-frequency components of the voltage and current at the protection installations on both sides of the transmission line at each sampling point are obtained.

S22, based on the 1-mode high-frequency components of the voltage and current at the protection installations on both sides of the transmission line for each of the sampling points, the 1-mode action impedance of the transmission line for each of the sampling points is obtained.

S23, based on the 1-mode action impedance of the transmission line for all the sampling points during one sampling period after the fault, the 1-mode transient action impedance difference of the transmission line is obtained.

When implemented, the 1-mode transient action impedance difference of the transmission line is expressed as:

$${S}_{act} ( {ω}_{f} ) = \frac{1}{H} {\sum }_{h = 1}^{H} {( {Z}_{act 1 , h} ( {ω}_{f} ) - {Z}_{L} ( {ω}_{f} ) )}^{2}$$

In the formula, S_{act}(ω_{f}) represents the 1-mode transient action impedance difference when the high-frequency is ω_{f}, H represents the total number of the sampling points in a sampling period after the fault, Z_{act1,h}(ω_{f}) represents the 1-mode action impedance at the h-th sampling point when the high-frequency is ω_{f}, and Z_{L}(ω_{f}) represents the equivalent impedance of the transmission line when the high-frequency is ω_{f}.

In the specific implementation, when the high-frequency frequency of the h-th sampling point is ω_{f}, the 1-mode action impedance Z_{act1,h}(ω_{f}) is expressed as:

$${Z}_{act 1 , h} ( {ω}_{f} ) = \frac{{U}_{M 1 , h} ( {ω}_{f} )}{{I}_{M 1 , h} ( {ω}_{f} )} + \frac{{U}_{N 1 , h} ( {ω}_{f} )}{{I}_{N 1 , h} ( {ω}_{f} )}$$

In the above formula, U_{M1,h}(ω_{f}) and I_{M1,h}(ω_{f}) respectively represent the 1-mode voltage high-frequency component and the 1-mode current high-frequency component of the h-th sampling point when the high-frequency is ω_{f} at the wind farm side protection installation of the transmission line, U_{N1,h}(ω_{f}) and I_{N1,h}(ω_{f}) respectively represent the 1-mode voltage high-frequency component and the 1-mode current high-frequency component of the h-th sampling point when the high-frequency is ω_{f} at the flexible DC side protection installation of the transmission line.

S3, based on the 1-mode transient action impedance difference and fault identification criterion of the transmission line, it is to determine whether the fault inside the area of the transmission line occurs; if so, the protection action of the transmission line is started.

When implemented, the fault identification criteria include:

S_{act}(ω_{f})≥Sₛₑₜ(ω_{f})

In the formula, Sₛₑₜ(ω_{f}) represents the threshold value of the 1-mode transient action impedance difference of the transmission line when the high-frequency is ω_{f};

If S_{act}(ω_{f}) satisfies the fault identification criterion, it is judged to be a fault inside the area of the transmission line; otherwise, it is judged to be a fault outside the area of the transmission line.

Specifically, when the high-frequency is ω_{f}, the threshold value Sₛₑₜ(ω_{f}) of the 1-mode transient action impedance difference of the transmission line satisfies:

S_{actmin}^{out}(ω_{f})<Sₛₑₜ(ω_{f})<S_{actmax}ⁱⁿ(ω_{f})

Where, S_{actmax}ⁱⁿ(ω_{f}) represents the maximum value of the fault inside the area of the transmission line when the high-frequency is ω_{f}, and S_{actmin}^{out}(ω_{f}) represents the minimum value of the fault outside the area of the transmission line when the high-frequency is ω_{f}.

Specifically, the maximum value S_{actmax}ⁱⁿ(ω_{f}) of the fault inside the area of the transmission line when the high-frequency is ω_{f} is expressed as:

$${S}_{actmax}^{i n} ( {ω}_{f} ) = {( {Z}_{f c} ( {ω}_{f} ) + {z}_{mmc 1} ( {ω}_{f} ) + {z}_{L} ( {ω}_{f} ) - {Z}_{f c} ( {ω}_{f} ) \frac{{i}_{fc 1} ( {ω}_{f} )}{{i}_{M 1} ( {ω}_{f} )} - \frac{{u}_{mmc 1} ( {ω}_{f} )}{{i}_{N 1} ( {a}_{f} )} )}^{2}$$

Where, Z_{fc}(ω_{f}) represents the equivalent impedance of the wind field side at the high-frequency of ω_{f}, Z_{mmc1}(ω_{f}) represents the 1-mode equivalent impedance of the flexible DC side at the high-frequency of ω_{f}, i_{fc1}(ω_{f}) represents the 1-mode equivalent transient current source of the wind field side at the high-frequency of ω_{f}, u_{mmc1}(ω_{f}) represents the 1-mode transient voltage source of the flexible DC side at the high-frequency of ω_{f}, i_{M1}(ω_{f}) represents the 1-mode current high frequency component of the wind field side of the transmission line at the protection installations at any sampling time when the high-frequency is ω_{f}, i_{N1}(ω_{f}) represents the 1-mode current high frequency component of the flexible DC side of the transmission line at the protection installations at any sampling time when the high-frequency is ω_{f};

The minimum value S_{actmin}^{out}(ω_{f}) of the fault outside the area of the transmission line when the high-frequency is ω_{f} is expressed as:

S_{actmin}^{out}(ω_{f})=Z_{L}²(ω_{f}).

Specifically, the high-frequency ω_{f} is taken as ωₘₐₓ; ωₘₐₓ is determined by the following way:

$${ω}_{max} = max \{ {ω}_{1} , {ω}_{2} , … , {ω}_{6} \}$$

In the formula, ω₁˜ω₆ are the frequency solutions when the derivative of the 1-mode action impedance difference of the transmission line is equal to 0, respectively, and max{ }represents the maximum value.

Specifically, the 1-mode action impedance difference ΔZ_{act1}(ω_{f}) of the transmission line is expressed as:

$$Δ {Z}_{act 1} ( {ω}_{f} ) = \frac{{A}_{7} {ω}_{f}^{7} + {A}_{5} {ω}_{f}^{5} + {A}_{3} {ω}_{f}^{3} + {A}_{1} {ω}_{f}}{{B}_{6} {ω}_{f}^{6} + {B}_{4} {ω}_{f}^{4} + {B}_{2} {ω}_{f}^{2} + {B}_{0}}$$

In the formula, A₇, A₅, A₃, A₁, B₆, B₄, B₂, B₀ are constants calculated according to the fault transient model on both sides of the transmission line.

It should be noted that the line protection method of the wind farm connected to the flexible DC system in this embodiment is based on the following derivation:

Firstly, based on the control system and electrical parameters of the direct-drive wind turbine, the transient model of the wind turbine in the frequency domain is derived. Combined with the topology of the wind farm collection line system, the equivalent impedance of the wind field and the controlled current source are obtained.

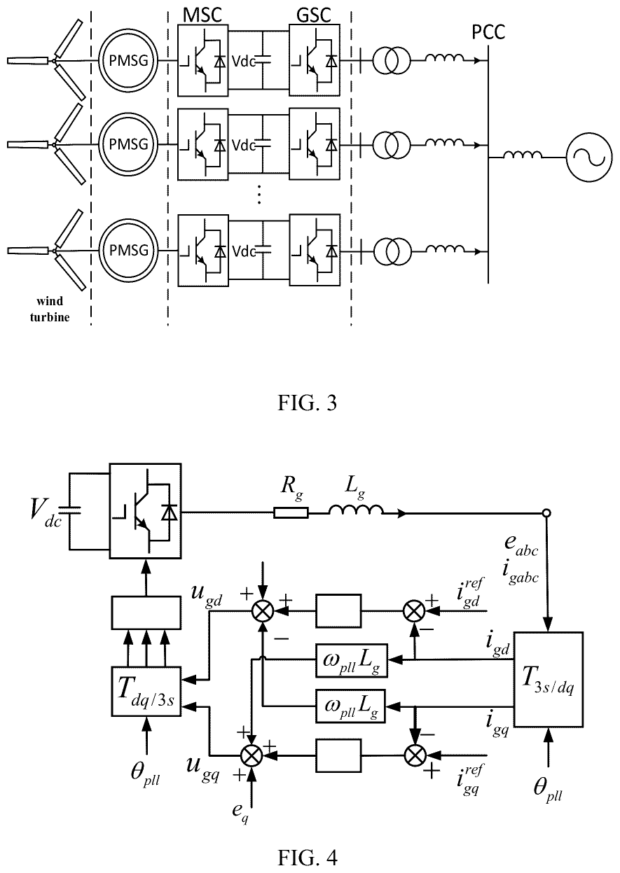

The schematic diagram of the transmission line of the wind farm connected to the flexible DC system is shown in 2. The two sides of the transmission line MN are connected to the wind farm station and the flexible DC transmission system respectively, that is, the wind farm side and the flexible DC side of the transmission line. The grid-connected system of direct-drive wind farm is shown in FIG. 3. Permanent magnet direct-drive wind turbine (PMSG) is composed of mechanical system, permanent magnet synchronous generator and full power wind power converter. Among them, the permanent magnet synchronous generator applies permanent magnet excitation, and there is no excitation coil winding on the stator, so the copper loss is low and the power generation efficiency is high. The full-power wind power converter decouples the generator-side converter MSC and the grid-side converter GSC through the DC tie-line, and the DC bus capacitance is large enough, and the dynamic change of the generator-side system has little effect, which is simplified as a constant power source.

The topology and control block diagram of the network side converter of the direct drive wind turbine are shown in FIG. 4. The DC bus capacitor supports the DC side voltage V_{dc}, and the grid side converter is connected with an L-type filter with resistance R_{g} and inductance L_{g}, which is boosted by the terminal transformer and incorporated into the AC power grid. According to the principle of Park transformation, the time domain voltage equation is transformed by Laplace transform, and the complex frequency domain voltage equation of the grid-side converter in the synchronous rotating coordinate system is obtained as follows:

$$\{ \begin{matrix}{u}_{gd} = ( {R}_{g} + s {L}_{g} ) {i}_{gd} - {ω}_{s} {L}_{g} {i}_{gq} + {e}_{d} \\ {u}_{gq} = ( {R}_{g} + s {L}_{g} ) {i}_{gq} + {ω}_{s} {L}_{g} {i}_{gd} + {e}_{q}\end{matrix} \qquad ( 1 )$$

In the formula, s denotes the Laplacian operator; u_{gd} and u_{gq} are the port voltage of the grid-side converter in the d-axis and q-axis coordinate systems, respectively; i_{gd} and i_{gq} are the port output current of the grid-side converter in the d-axis and q-axis coordinate systems, respectively; e_{d} and e_{q} are the port voltage of the direct-drive wind turbine in the d-axis and q-axis coordinate systems, respectively; ωₛ is the synchronous angular velocity.

The grid-side converter adopts grid voltage oriented vector control to stabilize the DC voltage, control the input power factor, and transmit the active power to the grid immediately. During the steady-state operation of the wind turbine, the output phase angle of the phase-locked loop can accurately track the actual grid phase angle, so that the d-axis voltage is oriented to the grid voltage.

In the dq rotating coordinate system, the complex frequency domain vector control equation of the direct drive wind turbine is:

$$\{ \begin{matrix}{u}_{g d} = ( {K}_{g p} + \frac{{K}_{gi}}{s} ) ( {i}_{gd}^{ref} - {i}_{gd} ) - {ω}_{s} {L}_{g} {i}_{gq} + {e}_{d} \\ {u}_{gq} = ( {K}_{g p} + \frac{{K}_{gi}}{s} ) ( {i}_{gq}^{ref} - {i}_{gq} ) - {ω}_{s} {L}_{g} {i}_{gd} + {e}_{q}\end{matrix} \qquad ( 2 )$$

In the formula, i_{gd}^{ref} is the d-axis current reference value of the grid-side converter, which is controlled by the DC link voltage; i_{gq}^{fef} is the q-axis current reference value of the grid-side converter; K_{gp} and K_{gi} are the proportional coefficient and integral coefficient of the current inner loop PI regulator, respectively.

At the moment of failure of the power grid, due to the change of the topological structure of the power grid, the amplitude and phase of the voltage at the grid-connected point will change abruptly, and the phase-locked loop coordinate axis cannot immediately keep up with the coordinate transformation of the voltage at the grid-connected point. Therefore, considering the dynamic characteristics of the phase-locked loop after the fault, there is an error Δθₚₗₗ between the phase detected by the phase-locked loop and the actual terminal voltage phase, which is expressed as:

$$Δ {θ}_{p l l} = {θ}_{u} - {θ}_{p l l} \qquad ( 3 )$$

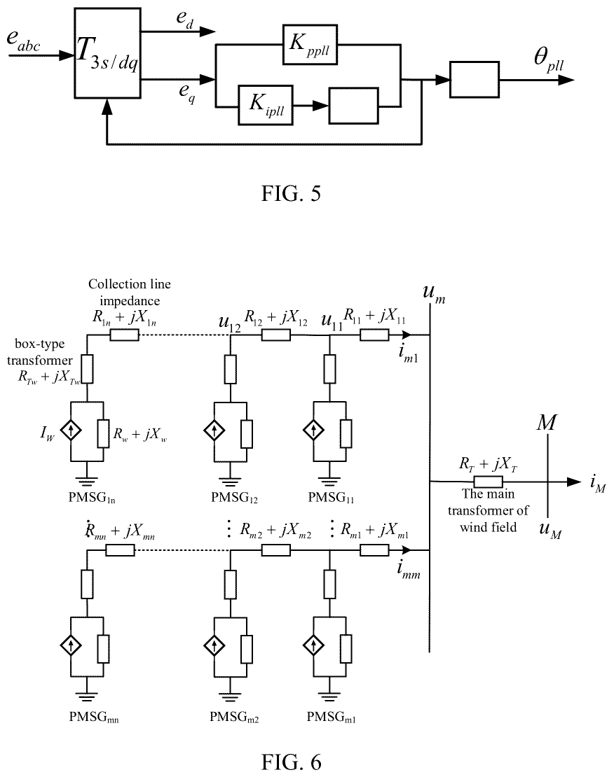

The control block diagram of the phase-locked loop is shown in FIG. 5. The vector control equation in the complex frequency domain is:

$${θ}_{p l l} = \frac{1}{s} ( {K}_{p p l l} + \frac{{K}_{i p l l}}{s} ) {e}_{q} \qquad ( 4 )$$

In the formula, θₚₗₗ is the output electrical angle of the phase-locked loop; θᵤ is the actual electrical angle of the power grid after the fault; Kₚₚₗₗ and Kᵢₚₗₗ are the proportional coefficient and integral coefficient of the phase-locked loop PI control, respectively.

The parameters of the actual power grid and the phase-locked loop satisfy the following formula:

$$[ \begin{matrix}{x}_{d}^{s} \\ {x}_{q}^{s}\end{matrix} ] = [ \begin{matrix}cos {Δθ}_{p l l} & sin {Δθ}_{p l l} \\ - sin {Δθ}_{p l l} & cos {Δθ}_{p l l}\end{matrix} ] [ \begin{matrix}{x}_{d}^{p} \\ {x}_{q}^{p}\end{matrix} ] \qquad ( 5 )$$

In the formula, x_{d}^{s} and x_{q}^{x} are the d and q axis parameters in the actual grid input coordinate system; x_{d}^{p} and x_{q}^{p} are the d and q axis parameters in the phase-locked loop coordinate system, respectively.

After the grid fault, the grid-side converter uses the phase-locked loop output angle for coordinate transformation. At this time, the vector control equation is:

$$\{ \begin{matrix}{u}_{gd}^{′} = ( {K}_{gp} + \frac{{K}_{gi}}{s} ) ( {i}_{gd}^{′ ref} - {i}_{gd}^{′} ) - {ω}_{pll} {L}_{g} {i}_{gq}^{′} + {e}_{d}^{′} \\ {u}_{gq}^{′} = ( {K}_{gp} + \frac{{K}_{gi}}{s} ) ( {i}_{gq}^{′ ref} - {i}_{gq}^{′} ) + {ω}_{pll} {L}_{g} {i}_{gd}^{′} + {e}_{q}^{′}\end{matrix} \qquad ( 6 )$$

In the formula, u′_{gd} and u′_{gq} are the d and q axis components of the grid-side converter voltage after the fault respectively; i′_{gd} and i′_{gq} are the d-axis and q-axis components of the grid-side converter current after the fault; e′_{d} and e′_{q} are the d-axis and q-axis voltages of the wind turbine port after the fault; i′_{gd}^{ref}, i′_{gq}^{ref} are the d-axis and q-axis current reference values of the grid-side converter after the fault; ωₚₗₗ is the output angular velocity of the phase-locked loop after fault.

By combining equations (1), (5) and (6) and using Park transformation to the three-phase stationary coordinate system, the fault short-circuit current of the direct-drive wind turbine in the frequency domain can be obtained as follows:

$${i}_{pmsg} = {Y}_{w} {e}_{pmsg} + {I}_{w} \qquad ( 7 )$$

In the formula,

$${Y}_{w} = \frac{\frac{\begin{matrix}( 1 + j \frac{1}{{ω}_{p} - {ω}_{s}} ) \\ ( 1 - j \frac{1}{{ω}_{p} - {ω}_{s}} {E}_{s} ( {K}_{p p l l} - j \frac{{K}_{ipll}}{{ω}_{p} - {ω}_{s}} ) ) + j {θ}_{u}\end{matrix}}{( 1 - j \frac{1}{{ω}_{p} - {ω}_{s}} {E}_{s} ( {K}_{p p l l} - j \frac{{K}_{ipll}}{{ω}_{p} - {ω}_{s}} ) ) + j {θ}_{u}}}{\begin{matrix}{K}_{gp} - j \frac{{K}_{gi}}{{ω}_{p} - {ω}_{s}} + {R}_{g} + j ( {ω}_{p} - {ω}_{s} ) {L}_{g} - \\ \frac{{( {ω}_{p} - {ω}_{s} )}^{3}}{{( {ω}_{p} - {ω}_{s} )}^{2} - {E}_{s} ( j ( {ω}_{p} - {ω}_{s} ) {K}_{ppll} + {K}_{ipll} )} {θ}_{u} {L}_{g}\end{matrix}}$$

$${I}_{w} = \frac{( {K}_{g p} - \frac{j {K}_{gi}}{( {ω}_{p} - {ω}_{s} ) - j \frac{{( {ω}_{p} - {ω}_{s} )}^{3}}{\begin{matrix}{( {ω}_{p} - {ω}_{s} )}^{2} - \\ {E}_{s} ( j ( {ω}_{p} - {ω}_{s} ) {K}_{ppll} + {K}_{ipll} )\end{matrix}} {θ}_{u}} ) {i}_{gdq}^{′ ref}}{\begin{matrix}{K}_{g p} - j \frac{{K}_{gi}}{{ω}_{p} - {ω}_{s}} + {R}_{g} + j ( {ω}_{p} - {ω}_{s} ) {L}_{g} - \\ \frac{{( {ω}_{p} - {ω}_{s} )}^{3}}{{( {ω}_{p} - {ω}_{s} )}^{2} - {E}_{s} ( j ( {ω}_{p} - {ω}_{s} ) {K}_{ppll} + {K}_{ipll} )}\end{matrix} {θ}_{u} {L}_{g}}$$

$${i}_{qdg}^{′ ref} = {i}_{gd}^{′ ref} + {ji}_{gq}^{′ ref}$$

In the formula, Eₛ is the steady-state voltage amplitude of the wind turbine port after the fault; e_{pmsg} and i_{pmsg} are the three-phase voltage and current of the grid-connected point of the wind turbine port after the fault; Y_{W} is the equivalent admittance of wind turbine after fault; I_{w} is the equivalent current source of wind turbine after fault; ωₚ is the p-th harmonic angular velocity.

The chain connection mode is adopted in the direct-drive wind farm. There are n direct-drive wind turbines running in parallel on each collection line, and the whole wind farm is composed of m collection lines. The fault transient network of the wind farm station is shown in FIG. 6. According to FIG. 6, the output short-circuit current of the M side of the transmission line is solved.

Considering the conversion of converter transformer ratio, the voltage and current equations of a single collection line of wind farm are:

$$\{ \begin{matrix}{u}_{i 1} = {u}_{m} + {Z}_{i 1} {i}_{m 1} \\ {u}_{i 2} = {u}_{i 1} + {Z}_{i 2} ( {i}_{m 2} - \frac{{u}_{i 1} - {k}_{T w i}^{2} {Z}_{w i} {I}_{w}}{{k}_{T w i}^{2} {Z}_{w i} + {Z}_{T w i}} ) \\ ⋮ \\ {u}_{i n} = {u}_{i n - 1} + {Z}_{i n} ( {i}_{m i} - \frac{{u}_{i 1} + … + {u}_{i n - 1} - ( n - 1 ) {k}_{T w i}^{2} {Z}_{w i} {I}_{w}}{{k}_{T w i}^{2} {Z}_{w i} + {Z}_{T w i}} )\end{matrix} \qquad ( 8 )$$

In the formula, uₘ is the PCC point voltage of the wind farm in the fault transient network; iₘᵢ is the output current of the i-th collection line of the wind farm station, i=1, . . . , m; uᵢₖ is the voltage at the port of the k-th wind turbine on the i-th collection line, k=1, . . . , n; Zᵢₖ is the line impedance of the k-th wind turbine port on the i-th collection line; Z_{wi} is the equivalent impedance of the direct-drive wind turbine on the i-th collection line; k_{Twi} is the ratio of box-type transformer at the wind turbine port on the i-th collection line; Z_{Twi} is the equivalent impedance of the box-type transformer at the wind turbine port.

The transient model of a single collection line in the station is obtained by iteration of Eq. (8):

$${u}_{m} = {Z}_{c i} {i}_{m i} + {U}_{c i} \qquad ( 9 )$$

In the formula,

$${Z}_{ci} = {Z}_{i 1} + \frac{{Z}_{i 2}}{{m}_{i 2}} + \frac{{Z}_{i 3}}{( 1 + {m}_{i 2} ) {m}_{i 3}} + \frac{{Z}_{i 4}}{[ 1 + ( 1 + {m}_{i 2} ) {m}_{i 3} ] {m}_{i 4}} + … + \frac{{Z}_{i n}}{\{ 1 + [ 1 + ( … ) {m}_{i ( n - 2 )} ] {m}_{i ( n - 1 )} \} {m}_{i n}}$$

$${U}_{ci} = \frac{{k}_{ci} {k}_{Twi} {Z}_{wi} {I}_{wi}}{{k}_{Twi}^{2} {Z}_{wi} + {Z}_{Twi}}$$

$${m}_{ik} = 1 + \frac{{Z}_{ik}}{{k}_{Twi}^{2} {Z}_{wi} + {Z}_{Twi}}$$

$${k}_{ci} = \frac{{Z}_{i 2}}{{m}_{i 2}} + ( 1 + \frac{1}{{m}_{i 2}} ) \frac{{Z}_{i 3}}{( 1 + {m}_{i 2} ) {m}_{i 3}} + ( 1 + \frac{1}{( 1 + {m}_{i 2} ) {m}_{i 3}} ) \frac{{Z}_{i 4}}{[ 1 + ( 1 + {m}_{i 2} ) {m}_{i 3} ] {m}_{i 4}} + … + \{ 1 + \frac{1}{[ 1 + ( … ) {m}_{i ( n - 2 )} ] {m}_{i ( n - 1 )}} \} \frac{{Z}_{i n}}{\{ 1 + [ 1 + ( … ) {m}_{i ( n - 2 )} ] {m}_{i ( n - 1 )} \} {m}_{i n}}$$

According to the topological structure of the wind farm in FIG. 6, the frequency domain expression of the current i_{M} of the transmission line outside the wind farm station satisfies the following relationship:

$$\{ \begin{matrix}{u}_{i 1} = {Z}_{c 1} {i}_{m 1} + {Z}_{T} {i}_{M} + {u}_{M} \\ {u}_{i 2} = {Z}_{c 2} {i}_{m 2} + {Z}_{T} {i}_{M} + {u}_{M} \\ ⋮ \\ {u}_{im} = {Z}_{cn} {i}_{m m} + {Z}_{T} {i}_{M} + {u}_{M} \\ {i}_{M} = {i}_{m 1} + {i}_{m 2} + … + {i}_{m m}\end{matrix} \qquad ( 10 )$$

$${Z}_{T} = {R}_{T} + j ω {L}_{T} \qquad ( 11 )$$

In the formula, u_{M} is the bus voltage on the M side of the transmission line; i_{M} is the current of the transmission line; Z_{ci} is the equivalent impedance of the i-th collection line in the wind farm station; Z_{T} is the impedance of the main transformer in the wind field, R_{T} is the resistance of the main transformer in the wind field, and L_{T} is the inductance of the main transformer in the wind field. ω is the output angular velocity of the system.

From Equation (10), a total of m collection lines in the station are iterated in turn, and the transient model of the wind farm in the frequency domain can be obtained as follows:

$${i}_{M} = {Y}_{f c} {u}_{M} + {i}_{f c} \qquad ( 12 )$$

In the formula,

$${Y}_{fc} = \frac{1}{{Z}_{fc}}$$

$${i}_{fc} = {\sum }_{i = 1}^{m} \frac{{U}_{ci}}{{Z}_{ci}}$$

$${Z}_{fc} = {Z}_{T} + {Z}_{c 1} // {Z}_{c 2} // … // {Z}_{c m}$$

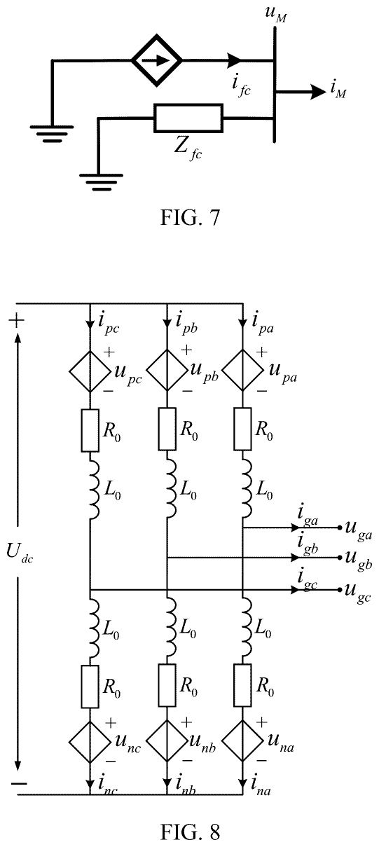

Therefore, it can be seen that the transient model of wind farm station can be regarded as the parallel form of impedance Z_{fc} and current source i_{fc}, and the frequency domain transient model is shown in FIG. 7.

Secondly, based on the flexible DC transmission system and electrical parameters, the transient model of the MMC converter in the frequency domain is derived, and the equivalent impedance and the controlled current source of the converter are obtained.

The modular multilevel converter (MMC) based high voltage direct current (HVDC) transmission system (MMC-HVDC) can independently adjust the active power and reactive power, and overcome the defect of commutation failure of traditional HVDC transmission. It has been widely used in large-scale offshore wind farms for long-distance transmission and grid connection. The basic structure of MMC is composed of half-bridge sub-module (SM), and the output power and voltage of MMC are controlled by increasing or decreasing the number of sub-modules. The topology diagram of the three-phase MMC converter is shown in FIG. 8. There are six bridge arms in the converter. Each phase is composed of upper and lower bridge arms. Each bridge arm is composed of resistance R₀, inductance L₀ and Nₐᵣₘ sub-modules in series. The reactor (inductance L₀) in the bridge arm plays the role of eliminating harmonics and suppressing fault current.

Among them, u_{gφ} is the φ phase voltage at the AC system side; i_{gφ} is the φ phase current at the AC system; the sum of the capacitor voltages of the upper and lower arm operation sub-modules of the AC system φ phase is respectively u_{pφ}, u_{nφ}; the upper and lower arm currents of the AC system φ phase are i_{pφ}, i_{nφ} respectively; U_{dc} is DC voltage measurement for MMC converter; in the above voltage and current variables, A, B and C phases are represented φ=A, B, C respectively.

The bridge arm capacitance is regarded as a whole. From the circuit structure of the MMC converter in FIG. 8, it can be seen that in the complex frequency domain, the voltage equations of the upper and lower arms of each phase are:

$$\{ \begin{matrix}{u}_{g φ} = \frac{{U}_{d c}}{2} - {u}_{p φ} - ( {sL}_{0} + {R}_{0} ) {i}_{p φ} \\ {u}_{g φ} = - \frac{{U}_{d c}}{2} + {u}_{n φ} + ( {sL}_{0} + {R}_{0} ) {i}_{n φ}\end{matrix} \qquad ( 13 )$$

$$\{ \begin{matrix}{sC}_{arm} {u}_{cp φ} = {m}_{p φ} {i}_{p φ} \\ {sC}_{arm} {u}_{cn φ} = {m}_{n φ} {i}_{n φ}\end{matrix} \qquad ( 14 )$$

In the formula, Cₐᵣₘ is the equivalent capacitance of the bridge arm; u_{cpφ} and u_{cnφ} are the sum of the capacitor voltages of the upper and lower arms of the φ phase, respectively; m_{pφ} and m_{nφ} are the output voltage modulation functions of the upper and lower arms of the φ phase, respectively.

The circulating current i_{cirφ} of phase φ bridge arm in MMC converter is defined, and the calculation expression is as follows:

$${i}_{cir φ} = \frac{1}{2} ( {i}_{p φ} + {i}_{n φ} ) \qquad ( 15 )$$

The AC side current of MMC converter is expressed as:

$${i}_{g φ} = {i}_{p φ} - {i}_{n φ} \qquad ( 16 )$$

Combining Eqs. (13)-(16), the dynamic characteristic matrix equation of MMC AC side in complex frequency domain can be obtained as follows:

$$[ \begin{matrix}{u}_{cp φ} \\ {u}_{cn φ} \\ {i}_{cir φ} \\ {i}_{g φ}\end{matrix} ] = [ \begin{matrix}0 & 0 & \frac{{m}_{p φ}}{{sC}_{arm}} & \frac{{m}_{p φ}}{2 {sC}_{arm}} \\ 0 & 0 & \frac{{m}_{n φ}}{{sC}_{arm}} & - \frac{{m}_{n φ}}{2 {sC}_{arm}} \\ - \frac{{m}_{p φ}}{2 {sL}_{0}} & - \frac{{m}_{n φ}}{2 {sL}_{0}} & - \frac{{R}_{0}}{{sL}_{0}} & 0 \\ - \frac{{m}_{p φ}}{{sL}_{0}} & \frac{{m}_{n φ}}{{sL}_{0}} & 0 & - \frac{{R}_{0}}{{sL}_{0}}\end{matrix} ] [ \begin{matrix}{u}_{cp φ} \\ {u}_{cn φ} \\ {i}_{cir φ} \\ {i}_{g φ}\end{matrix} ] + [ \begin{matrix}0 & 0 \\ 0 & 0 \\ \frac{1}{2 {sL}_{0}} & 0 \\ 0 & - \frac{2}{{sL}_{0}}\end{matrix} ] [ \begin{matrix}{U}_{d c} \\ {u}_{g φ}\end{matrix} ] \qquad ( 17 )$$

By solving Eq. (17), the MMC AC-side fault transient model in frequency domain can be obtained as follows:

$${u}_{g φ} = - {Z}_{mmc φ} {i}_{g φ} + {u}_{mmc φ} \qquad ( 18 )$$

In the formula,

$${Z}_{mmc φ} = \frac{1}{2} \{ \begin{matrix}( j ω {L}_{0} + {R}_{0} ) + \frac{{m}_{p φ}^{2} + {m}_{n φ}^{2}}{2 j ω {C}_{0}} \\ - \frac{{( {m}_{p φ}^{2} - {m}_{n φ}^{2} )}^{2}}{2 j ω {C}_{0} [ 2 j ω {C}_{0} ( j ω {L}_{0} + {R}_{0} ) + {m}_{p φ}^{2} + {m}_{n φ}^{2} ]}\end{matrix} \}$$

$${u}_{mmc φ} = - \frac{1}{2} \frac{( {m}_{p φ}^{2} - {m}_{n φ}^{2} ) {U}_{d c}}{2 j ω {C}_{0} ( j ω {L}_{0} + {R}_{0} ) + {m}_{p φ}^{2} + {m}_{n φ}^{2}}$$

$${C}_{0} = {N}_{arm} {C}_{arm}$$

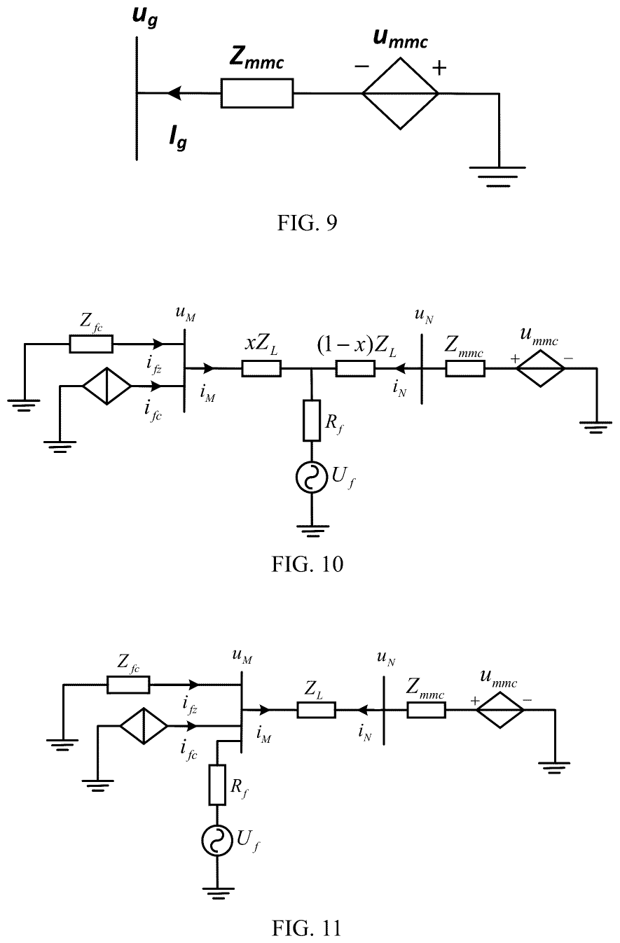

Therefore, it can be seen that the output transient short-circuit current of the converter after the AC side fault of the flexible DC system is related to the output modulation function of the control system and the internal electrical parameters of the converter. The frequency domain transient model can be regarded as the series form of the impedance Z_{mmc} and the controlled voltage source u_{mmc}. The model diagram is shown in FIG. 9.

Thirdly, based on the fault transient model of the transmission line of wind field connected to the flexible DC system after fault, the action impedance of the line protection installation under different faults is analyzed respectively, and the difference of the transient action impedance in the fault transient network in and outside the area is determined.

According to the fault analysis theory, the three-phase circuit can be decoupled into three modules for analysis. The operation formula is as follows:

$$[ \begin{matrix}{F}_{1} \\ {F}_{2} \\ {F}_{0}\end{matrix} ] = \frac{1}{3} [ \begin{matrix}2 & - 1 & - 1 \\ 0 & \sqrt{3} & - \sqrt{3} \\ 1 & 1 & 1\end{matrix} ] [ \begin{matrix}{F}_{A} \\ {F}_{B} \\ {F}_{C}\end{matrix} ] \qquad ( 19 )$$

In the formula, F_{A}, F_{B}, F_{C} represent three-phase electrical quantities respectively, and F₁, F₂, F₀ represent decoupled 1-mode, 2-mode and 0-mode electrical quantities respectively.

Substituting the three-phase voltage and current on both sides of the transmission line into Formula (19), the 1-mode voltage and current can be obtained:

$$\{ \begin{matrix}{u}_{M 1} = \frac{1}{3} ( 2 {u}_{MA} - {u}_{MB} - {u}_{MC} ) \\ {i}_{M 1} = \frac{1}{3} ( 2 {i}_{MA} - {i}_{MB} - {i}_{MC} )\end{matrix} \qquad ( 20 )$$

$$\{ \begin{matrix}{u}_{N 1} = \frac{1}{3} ( 2 {u}_{NA} - {u}_{NB} - {u}_{NC} ) \\ {i}_{N 1} = \frac{1}{3} ( 2 {i}_{NA} - {i}_{NB} - {i}_{NC} )\end{matrix} \qquad ( 21 )$$

In the formula, u_{M1} and u_{M1} represent the 1-mode voltage and 1-mode current at the M-side protection installation of the transmission line respectively; u_{MA}, u_{MB} and u_{MC} respectively represent the A, B and C phase voltages at the M-side protection installation of the transmission line; i_{MA}, i_{MB} and i_{MC} respectively represent the A, B, and C phase currents at the M-side protection installation of the transmission line; u_{N1} and i_{N1} respectively represent the 1-mode voltage and 1-mode current at the M-side protection installation of the transmission line; u_{NA}, u_{NB} and u_{NC} respectively represent the A, B and C phase voltages at the M-side protection installation of the transmission line; i_{NA}, i_{NB} and i_{NC} represent the A, B, and C phase currents at the M-side protection installation of the transmission line, respectively.

When a fault inside the area of the transmission line occurs in the wind field connected to the flexible DC system, the transient impedance model of the wind field and the flexible DC system is integrated to construct the transient network when the fault inside the area of the transmission line occurs, as shown in FIG. 10. Among them, R_{f} and U_{f} are the grounding resistance and fault voltage of the fault point respectively; Z_{L} is the equivalent impedance of the transmission line; x is the percentage of the fault point to the M-side fault location.

According to FIG. 10, the protection installation on both sides of the transmission line takes the bus inflow line as the positive direction of the current, and the relationship between the voltage and current on the M side of the transmission line and the N side of the transmission line is:

$$\{ \begin{matrix}\frac{{u}_{M φ}}{{i}_{M φ}} = - {Z}_{fc} + {Z}_{fc} \frac{{i}_{fc φ}}{{i}_{M φ}} \\ \frac{{u}_{N φ}}{{i}_{N φ}} = - {Z}_{mmc φ} + \frac{{u}_{mmc φ}}{{i}_{N φ}}\end{matrix} \qquad ( 22 )$$

In the formula, u_{Mφ},and i_{Mφ}, are the φ-phase voltage and current on the M side of the wind field in the fault transient network, respectively; u_{Nφ} and i_{Nφ} are the N-side φ-phase voltage and current of the MMC-HVDC system in the fault transient network; i_{fcφ} is the equivalent transient current source of φ-phase wind field; Z_{fc} is the equivalent transient impedance of wind field; among the above voltage and current variables, φ=A, B, C.

By combining equations (20) and (21), the relationship between 1-mode voltage and 1-mode current when a fault occurs inside the area of the transmission line can be obtained as follows:

$$\{ \begin{matrix}\frac{{u}_{M 1}}{{i}_{M 1}} = \frac{2 {u}_{MA} - {u}_{MB} - {u}_{MC}}{2 {i}_{MA} - {i}_{MB} - {i}_{MC}} \\ \frac{{u}_{N 1}}{{i}_{N 1}} = \frac{2 {u}_{NA} - {u}_{NB} - {u}_{NC}}{2 {i}_{NA} - {i}_{NB} - {i}_{NC}}\end{matrix} \qquad ( 23 )$$

Define Zᵣₑₛ₁ as the 1-mode braking impedance of the transmission line and Z_{act1} as the 1-mode action impedance of the transmission line. The expressions are as follows:

$${Z}_{r e s 1} = \frac{{u}_{M 1}}{{i}_{M 1}} - \frac{{u}_{N 1}}{{i}_{N 1}} \qquad ( 24 )$$

$${Z}_{a c t 1} = \frac{{u}_{M 1}}{{i}_{M 1}} + \frac{{u}_{N 1}}{{i}_{N 1}} \qquad ( 25 )$$

Combining Eqs. (22)-(25), the 1-mode braking impedance and 1-mode action impedance when a fault occurs inside the area of the transmission line are:

$$\{ \begin{matrix}{Z}_{r e s 1} = - {Z}_{fc} + {Z}_{m m c 1} + {Z}_{fc} \frac{{i}_{fc 1}}{{i}_{M 1}} - \frac{{u}_{m m c 1}}{{i}_{N 1}} \\ {Z}_{act 1} = - {Z}_{fc} - {Z}_{m m c 1} + {Z}_{fc} \frac{{i}_{fc 1}}{{i}_{M 1}} + \frac{{u}_{m m c 1}}{{i}_{N 1}}\end{matrix} \qquad ( 26 )$$

In the formula, i_{fc1} is a 1-mode equivalent transient current source on the wind farm side and u_{mmc1} is a 1-mode equivalent controlled voltage source on the flexible DC side, which are obtained by substituting formula (12) and formula (18) into formula (19) respectively.

The above analysis shows that when the fault occurs inside the area of the transmission line, the 1-mode braking impedance and 1-mode action impedance at the protection installation on both sides are related to the 1-mode current flowing through the protection installation, which changes with the transient frequency.

When a fault occurs on the wind field side outside the area of the transmission line, the transient network under this fault scenario is shown in FIG. 11.

According to FIG. 11, the relationship between the voltage and current of each phase on the M side of the transmission line and the N side of the transmission line is:

$$\{ \begin{matrix}\frac{{u}_{M φ}}{{i}_{M φ}} = {Z}_{L} + {z}_{mmc φ} + \frac{{u}_{mmc φ}}{{i}_{M φ}} \\ \frac{{u}_{N φ}}{{i}_{N φ}} = - {Z}_{mmc φ} + \frac{{u}_{mmc φ}}{{i}_{N φ}}\end{matrix} \qquad ( 27 )$$

Combining Eqs. (23)-(25) and (27), the 1-mode braking impedance and 1-mode action impedance when the M-side fault outside the area of the transmission line is obtained are:

$$\{ \begin{matrix}{Z}_{r e s 1} = {Z}_{L} + 2 {Z}_{m m c 1} - 2 \frac{{u}_{m m c 1}}{{i}_{N 1}} \\ {Z}_{act 1} = {Z}_{L}\end{matrix} \qquad ( 28 )$$

The above analysis shows that when the wind field side fault occurs outside the area of the transmission line, the 1-mode braking impedance measured at the protection installations on both sides is related to the 1-mode current flowing through the protection installation, which changes with the transient frequency. The 1-mode action impedance is the equivalent impedance of the transmission line, which is a constant value and does not change with the transient frequency.

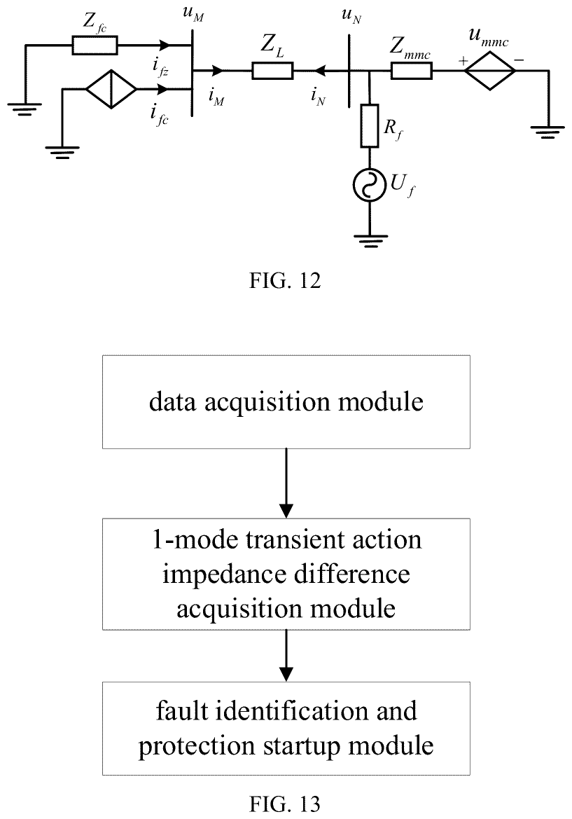

When a fault occurs on the N side outside the area of the transmission line, the transient network under this fault scenario is shown in FIG. 12.

According to FIG. 12, the relationship between the voltage and current of each phase on the M side of the transmission line and the N side of the transmission line is:

$$\{ \begin{matrix}\frac{{u}_{M φ}}{{i}_{M φ}} = - {Z}_{fc} + {Z}_{fc} \frac{{i}_{fc φ}}{{i}_{M φ}} \\ \frac{{u}_{N φ}}{{i}_{N φ}} = {Z}_{L} + {Z}_{fc} + {Z}_{fc} \frac{{i}_{fc φ}}{{i}_{N φ}}\end{matrix} \qquad ( 29 )$$

Combined with Formulas (23)-(25) and (29), the 1-mode braking impedance and 1-mode action impedance at the time of the wind field side fault outside the area of the transmission line is obtained as follows:

$$\{ \begin{matrix}{Z}_{res 1} = - {Z}_{L} - 2 {Z}_{fc} + 2 {Z}_{fc} \frac{{i}_{fc 1}}{{i}_{M 1}} \\ {Z}_{act 1} = {Z}_{L}\end{matrix} \qquad ( 30 )$$

The above analysis shows that when the MMC system side fault occurs outside the area of the transmission line, the 1-mode braking impedance measured at the protection installation on both sides is related to the 1-mode current flowing through the protection installation, which changes with the transient frequency. The 1-mode action impedance is the equivalent impedance of the transmission line, which is a constant value and does not change with the transient frequency.

Fourthly, based on the difference of the 1-mode action impedance at the protection installation of the transmission line during faults inside and outside the area of the transmission line, a fault identification criterion is constructed to identify the fault location of the transmission line.

The expression of 1-mode action impedance difference ΔZ_{act1} is defined as follows:

$${ΔZ}_{act 1} = {Z}_{act 1} - {Z}_{L} \qquad ( 31 )$$

In this embodiment, the variance is used to measure the matching between the 1-mode transient action impedance difference calculated by the voltage and current at the protection installation at both ends of the line and the fault scene. In order to ensure the accuracy of the results, this embodiment is calculated by averaging the results of multiple sampling points to ensure more accurate results. When the high-frequency frequency is ω_{f}, the expression of the 1-mode transient action impedance difference S_{act}(ω_{f}) is as follows:

$${S}_{act} ( {ω}_{f} ) = \frac{1}{H} {\sum }_{h = 1}^{H} {( Δ {Z}_{act 1} )}^{2} = \frac{1}{H} {\sum }_{h = 1}^{H} {( {Z}_{act , 1 , h} ( {ω}_{f} ) - {Z}_{L} )}^{2} \qquad ( 32 )$$

$$Where ,$$

$${Z}_{act , 1 , h} ( {ω}_{f} ) = \frac{{U}_{M1 , h} ( {ω}_{f} )}{{I}_{M1 , h} ( {ω}_{f} )} + \frac{{U}_{N 1 , h} ( {ω}_{f} )}{{I}_{N 1 , h} ( {ω}_{f} )}$$

In the formula, H represents the total number of sampling points in a sampling period after the fault, Z_{act1,h}(ω_{f}) represents the 1-mode action impedance of the h-th sampling point when the high-frequency is ω_{f}, Z_{L} represents the equivalent impedance of the transmission line, U_{M1,h}(ω_{f}) and I_{M1,h}(ω_{f}) represent the 1-mode voltage high-frequency component and the 1-mode current high-frequency component of the M-side protection installation at the h-th sampling point when the high-frequency is ω_{f}, U_{N1,h}(ω_{f}) and I_{N1,h}(ω_{f}) represent the 1-mode voltage high-frequency component and the 1-mode current high-frequency component of the N-side protection installation at the h-th sampling point, respectively.

In summary, the fault identification criteria that can be constructed include:

$${S}_{act} ( {ω}_{f} ) \geq {S}_{set} ( {ω}_{f} ) \qquad ( 33 )$$

In the formula, Sₛₑₜ(ω_{f}) represents the threshold value of the 1-mode transient action impedance difference of the transmission line at the high-frequency frequency ω_{f};

If S_{act}(ω_{f}) satisfies the fault identification criterion, it is judged to be a fault inside the area of the transmission line; otherwise, it is judged to be a fault outside the area of the transmission line.

Further, from the analysis of the third step, it can be seen that when the fault inside the area of the transmission line occurs, the difference between the calculated value of the 1-mode action impedance and the actual value (that is, the equivalent impedance Z_{L} of the transmission line) is not 0, which is a maximum value; in the case of the fault outside the area of the transmission line, the difference between the calculated value of 1-mode action impedance and the actual value is about 0, which is a minimum value. Therefore, the setting standard of the threshold value of 1-mode transient action impedance difference is as follows:

$$\{ \begin{matrix}{S}_{act max}^{in} ( {ω}_{f} ) = {( {Z}_{fc} ( {ω}_{f} ) + {Z}_{mmc 1} ( {ω}_{f} ) + {Z}_{L} ( {ω}_{f} ) - {Z}_{fc} ( {ω}_{f} ) \frac{{i}_{fc 1} ( {ω}_{f} )}{{i}_{M 1} ( {ω}_{f} )} - \frac{{u}_{mmc 1} ( {ω}_{f} )}{{i}_{N 1} ( {ω}_{f} )} )}^{2} \\ {S}_{act min}^{out} ( {ω}_{f} ) = {Z}_{L}^{2} ( {ω}_{f} )\end{matrix} \qquad ( 34 )$$

In the formula, S_{actmax}ⁱⁿ(ω_{f}) is the maximum value of the fault inside the area of the transmission line when the high-frequency is ω_{f}, and S_{actmin}^{out}(ω_{f}) is the minimum value of the fault outside the area of the transmission line when the high-frequency frequency is ω_{f}.

The threshold value of 1-mode transient action impedance difference should be greater than the minimum value S_{actmin}^{out} of the fault outside the area of the transmission line and less than the maximum value S_{actmax}ⁱⁿ of the fault inside the area of the transmission line, that is:

$${Z}_{L}^{2} ( {ω}_{f} ) < {S}_{set} ( {ω}_{f} ) < {( {Z}_{fc} ( {ω}_{f} ) + {Z}_{mmc} ( {ω}_{f} ) + {Z}_{L} ( {ω}_{f} ) - {Z}_{fc} ( {ω}_{f} ) \frac{{i}_{fc 1} ( {ω}_{f} )}{{i}_{M 1} ( {ω}_{f} )} - \frac{{u}_{mmc 1} ( {ω}_{f} )}{{i}_{N 1} ( {ω}_{f} )} )}^{2} \qquad ( 35 )$$

Further, according to the above analysis, it can be seen that the value in the fault identification criterion is related to the frequency of the selected high-frequency component. In this embodiment, in order to maximize the difference between the fault identification criteria when the faults inside and outside the area occur, the proposed protection method is more effective. The value of the high-frequency frequency is determined by the following method:

When the fault inside the area occurs, the 1-mode action impedance difference can be obtained at the fault inside the area from Eq. (31):

$$Δ {Z}_{act 1} = - {Z}_{L} = {Z}_{fc} \frac{{i}_{fc 1}}{{i}_{M 1}} + \frac{{u}_{mmc 1}}{{i}_{N 1}} - {Z}_{fc} - {Z}_{mmc 1} + {Z}_{L} \qquad ( 36 )$$

From the formula (36), it can be seen that the 1-mode action impedance difference at the fault inside the area is composed of wind field, transmission line and high-frequency transient model of MMC system. Combined with formulas (12) and (18), the impedance expression of 1-mode action impedance difference at high-frequency ω_{f} under the fault inside the area is obtained as follows:

$$Δ {Z}_{act 1} ( {ω}_{f} ) = \frac{{A}_{7} {ω}_{f}^{7} + {A}_{5} {ω}_{f}^{5} + {A}_{3} {ω}_{f}^{3} + {A}_{1} {ω}_{f}}{{B}_{6} {ω}_{f}^{6} + {B}_{4} {ω}_{f}^{4} + {B}_{2} {ω}_{f}^{2} + {B}_{0}} \qquad ( 37 )$$

In the formula, A₇, A₅, A₃, A₁, B₆, B₄, B₂ and B₀ are constants calculated according to the fault transient model on both sides of the transmission line, and A₇ and B₆ are greater than zero.

In order to distinguish the faults inside and outside the area of the transmission line more accurately, the maximum value of the 1-mode action impedance difference under the fault inside the area of the transmission line is selected as the frequency selection basis. Therefore, the derivation of the formula (37) is carried out, and the derivation analytical formula of the 1-mode action impedance difference is obtained.

The derivative analytic formula of the 1-mode action impedance difference under the fault inside the area is equal to 0, and the frequency solution ω₁˜ω₆ is calculated when the derivative analytic formula is equal to 0.

The maximum value of each frequency solution is selected as the value of high-frequency frequency, that is,

$${ω}_{max} = max \{ {ω}_{1} , {ω}_{2} , … , {ω}_{6} \} \qquad ( 38 )$$

In the formula, max{ }represents the maximum value.

Compared with the existing technology, this embodiment provides a line protection method based on the wind field connected to the flexible DC system. It can calculate the 1-mode transient action impedance difference at the protection installation of the transmission line based on the data collected after the fault, and accurately identify the faults inside and outside the area according to the fault identification criterion. It has fast action speed, is not affected by transition resistance, fault location and fault type, has high sensitivity, and has low sampling frequency. It is easy to implement in engineering, and fundamentally eliminates the problem of fault mis-operation and rejection of transmission line.

### Embodiment 2

A specific embodiment 2 of the application provides a line protection system for a wind farm connected to a flexible DC system, as shown in FIG. 13, including:

The data acquisition module is used to obtain the high-frequency components of voltage and current at the protection installations on both sides of the transmission line when the fault of the transmission line of the direct-drive wind field connected to the flexible DC system is monitored.

The 1-mode transient action impedance difference acquisition module is used to obtain the 1-mode transient action impedance difference of the transmission line based on the high-frequency components of the voltage and current at the protection installations on both sides of the transmission line.

The fault identification and protection startup module is used to determine whether a fault inside the area of the transmission line occurs based on the 1-mode transient action impedance difference and the fault identification criterion of the transmission line. If so, the protection action of the transmission line is started.

The specific implementation process of this embodiment of the application can be seen in the above method embodiment, and this embodiment is not repeated here.

Because the principle of this embodiment is same as that of the above method, the system also has the corresponding technical effect of the above method embodiment.

### Embodiment 3

In order to verify the correctness of the embodiments 1 and 2 of the application, the scheme in the above embodiments is tested and verified. The main parameters of the wind field connected flexible DC system are shown in Table 1.

TABLE 1
main parameters of the wind field connected
flexible DC system

| | |
|---|---|
| rated capacity of wind turbines | 1.8 MW |
| rated frequency of wind turbines | 50 Hz |
| rated voltage of wind turbines | 690 V |
| wind turbine converter transformer capacity | 2 MVA |
| wind turbine converter transformer ratio | 690 V/35 kV |
| impedance percentage of fan converter transformer | 9% |
| total number of wind turbines in the wind farm | 50 [symbol] |
| length of transmission line | 40 km |
| positive sequence resistance of transmission line | 0.0375Ω/km |
| positive sequence reactance of transmission line | 0.1767 H/km |
| zero sequence resistance of transmission line | 0.1125Ω/km |
| zero sequence reactance of transmission line | 0.5301 H/km |
| current inner loop integral parameter | 0.1683 |
| proportional parameter of phase-locked loop | 0.67 |
| integral parameters of phase-locked loop | 38.2 |
| MMC converter bridge arm resistance | 0.054Ω |
| MMC converter bridge arm inductance | 0.00054/pi H |
| MMC DC side voltage | 10 kV |

In this embodiment, the simulation verification is divided into the following three parts by taking the fault occurrence time as zero time, considering the influence of fault location and transition resistance:

The first part: the simulation verification results of different transition resistance faults inside the area of the transmission line.

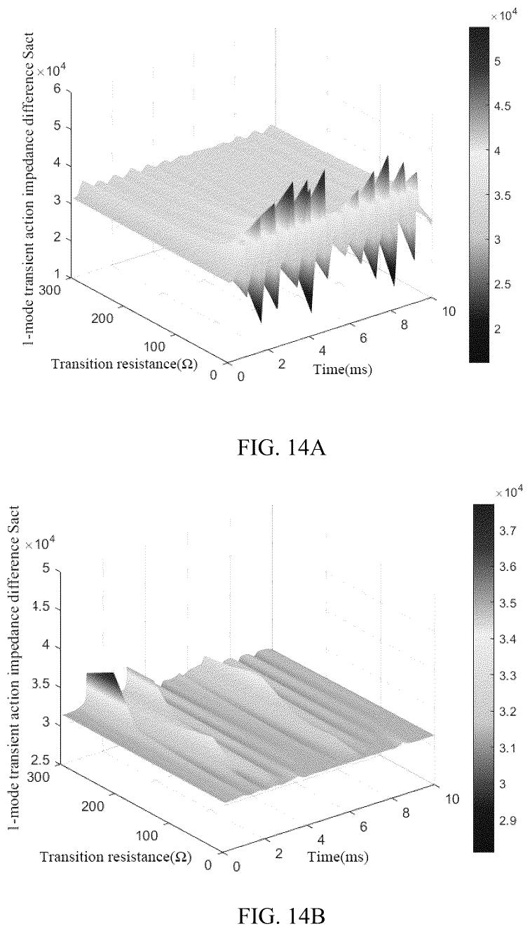

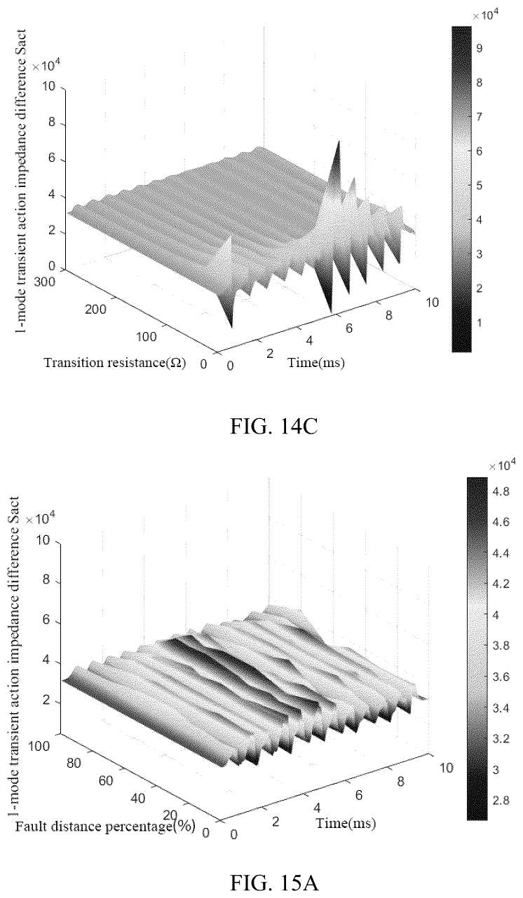

It is assumed that A-phase grounding fault, AB two-phase interphase fault and ABC three-phase fault occur at 50% of the transmission line respectively, and the transition resistance varies from 0 to 300Ω. The 1-mode transient action impedance difference at the protection installation under the above four fault conditions is shown in FIG. 14A, FIG. 14B, and FIG. 14C.

From FIG. 14A, FIG. 14B and FIG. 14C, it can be seen that when the A-phase grounding fault and ABC three-phase fault occur in the transmission line, the smaller the transition resistance, the more serious the fluctuation of S_{act}; when the AB two-phase interphase fault occurs inside the area of the transmission line, the greater the transition resistance, the more serious the fluctuation of S_{act}. However, under different fault conditions, S_{act} is greater than the threshold value Sₛₑₜ, and the protection is identified as a fault inside the area of the transmission line. When ABC three-phase fault occurs and the transition resistance is 1Ω, S_{act} has a maximum value of 96252.61 at t=6.15 ms. When the transition resistance of ABC three-phase fault is 1Ω, when t=5.95 ms, S_{act} has a minimum value of 8536.82, which is still much larger than the threshold value Sₛₑₜ. According to the above analysis, it can be seen that when a high-resistance fault occurs inside the area of the transmission line, the protection can act correctly, is not affected by the fault type, and has high sensitivity and fast identification ability.

The second part: Simulation verification results of faults at different positions inside the area of the transmission line.

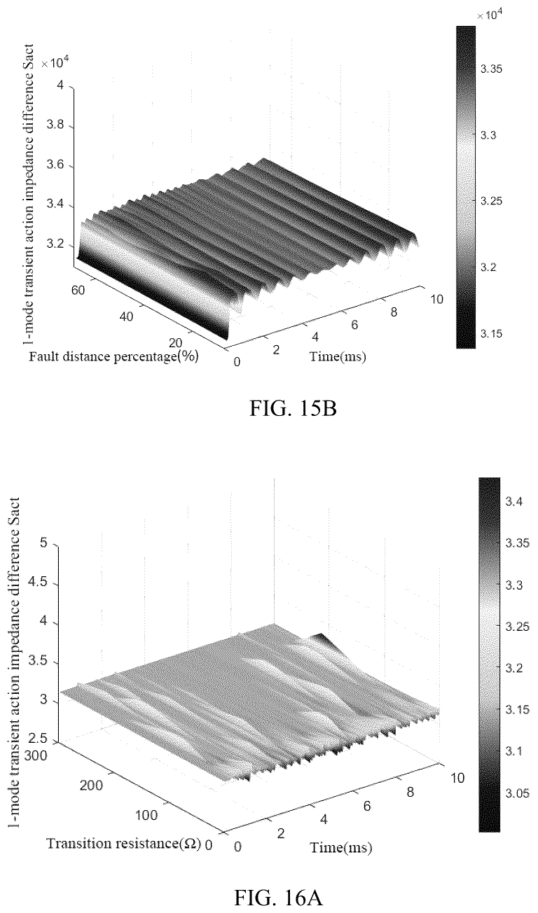

It is assumed that A-phase grounding fault and AB two-phase grounding fault occur at different positions inside the area of the transmission line respectively, and the transition resistance is 100Ω. The 1-mode transient action impedance difference at the protection installation under this fault condition is shown in FIG. 15A and FIG. 15B.

From FIG. 15A and FIG. 15B, it can be seen that when faults occur at different locations of the line, S_{act} fluctuates continuously with the fault time when phase A grounding fault occurs, and the fluctuation degree is large; when AB two-phase fault occurs, S_{act} first increases steadily and then fluctuates continuously, and the fluctuation degree is small. Under different fault conditions, it is greater than the threshold value, and the protection is identified as a fault inside the area of the transmission line. When the A-phase grounding fault occurs at 60% of the distance from the wind field side, when t=3.95 ms, S_{act} is the maximum value, and its value is 48862.66; when the A-phase grounding fault occurs at 80% of the distance from the M-terminal, when t=3.35 ms, S_{act} is the minimum value, and its value is 26668.36, which is still much larger than the threshold value Sₛₑₜ. According to the above analysis, it can be seen that the method proposed in Embodiment 1 can achieve accurate discrimination of the fault inside the area when faults occur at different positions of the transmission line. When a high-resistance fault occurs at the end of the line, it still has high sensitivity.

The third part: the simulation verification results of different transition resistance faults outside the area of the transmission line.

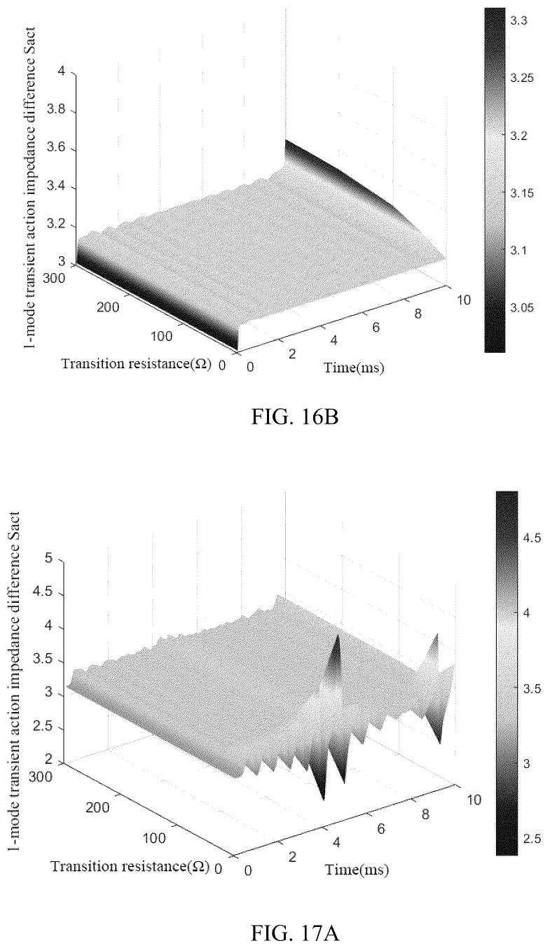

It is assumed that the AC two-phase grounding fault and the ABC three-phase fault occur on the wind field side outside the area of the transmission line respectively, and the transition resistance is 0˜300Ω. The 1-mode transient action impedance difference at the protection installation under this fault condition is shown in FIG. 16A and FIG. 16B.

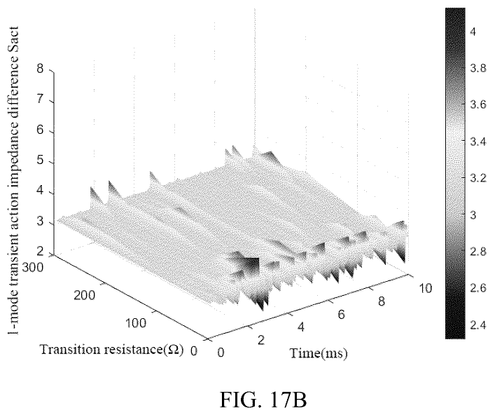

It is assumed that A-phase grounding fault and ABC three-phase fault occur on the flexible DC side outside the area of the transmission line respectively, and the transition resistance is 0˜300Ω. The 1-mode transient action impedance difference at the protection installation under this fault condition is shown in FIG. 17A and FIG. 17B.

From FIG. 16A and FIG. 16B, it can be seen that when the AC two-phase grounding fault and ABC three-phase fault occur on the wind field side outside the area, and the transition resistance is 0˜300Ω, the 1-mode transient action impedance difference Sac, measured at the protection installation is less than the threshold value, which is determined as the fault outside the area of the transmission line. When the AC interphase grounding fault occurs, the transition resistance is 200Ω, t=9.65 ms, and the 1-mode transient action impedance difference S_{act} has a maximum value of 3.428, indicating that no fault occurs inside the area of the transmission line, and the protection is reliable.

From FIG. 17A and FIG. 17B, it can be seen that when A-phase grounding fault and ABC three-phase fault occur on the flexible DC side outside the area, the 1-mode transient action impedance difference Sa, measured at the protection installation is less than the threshold value, which is determined to be a fault outside the area of the transmission line. When A phase grounding fault occurs, the transition resistance is 0.1Ω, t=4.7 ms, S_{act} has a maximum value of 4.806, indicating that there is no fault inside the area, and the protection is reliable and does not act.

From the above analysis, it can be concluded that when the fault of different transition resistance occurs outside the area of the transmission line, the method proposed in Embodiment 1 can accurately determine the occurrence of the fault outside the area, and the protection is reliable and does not act.

The skilled in the art can understand that the whole or part of the process of the above embodiments can be completed by computer program to instruct the relevant hardware, and the program can be stored in the computer readable storage medium. Among them, the computer readable storage medium is disk, optical disk, read-only storage memory or random storage memory.

The above mentioned is only the better specific implementation mode of the invention, but the protection scope of the invention is not limited to this. Any person skilled in the art can easily think of changes or replacements within the scope of the technology disclosed by the invention shall be covered within the protection scope of the invention.

What is claimed is:

1. A line protection method for wind farm connected to flexible DC system, comprising:
obtaining high frequency components of voltage and current at protection installations on both sides of a transmission line, when a fault of the transmission line of a direct drive wind field connected to flexible DC system is monitored;
obtaining 1-mode transient action impedance difference of the transmission line, based on the high-frequency components of voltage and current at the protection installations on both sides of the transmission line;
determining whether the fault inside the area of the transmission line occurs, based on the 1-mode transient action impedance difference and fault identification criterion of the transmission line, and starting the protection action of the transmission line if it is determined that the fault inside the area of the transmission line occurs.

2. The line protection method for wind farm connected to flexible DC system according to claim 1, wherein the 1-mode transient action impedance difference of the transmission line is obtained by the following way:
obtaining the 1-mode high-frequency components of the voltage and current at the protection installations on both sides of the transmission line for each of sampling points, based on the high-frequency components of the voltage and current at the protection installations on both sides of the transmission line for each of the sampling points;
obtaining the 1-mode action impedance of the transmission line for each of the sampling points, based on the 1-mode high-frequency components of the voltage and current at the protection installations on both sides of the transmission line for each of the sampling points;
obtaining the 1-mode transient action impedance difference of the transmission line, based on the 1-mode action impedance of the transmission line of all the sampling points in a sampling period after fault.

3. The line protection method for wind farm connected to flexible DC system according to claim 2, wherein the 1-mode transient action impedance difference of the transmission line is expressed as:
$${S}_{act} ( {ω}_{f} ) = \frac{1}{H} {\sum }_{h = 1}^{H} {( {Z}_{act , 1 , h} ( {ω}_{f} ) - {Z}_{L} ( {ω}_{f} ) )}^{2}$$
where, S_{act}(ω_{f}) represents the 1-mode transient action impedance difference when the high-frequency is ω_{f}, H represents the total number of the sampling points in the sampling period after fault, Z_{act1,h}(ω_{f}) represents the 1-mode action impedance at the h-th sampling point when the high-frequency is ω_{f}, and Z_{L}(ω_{f}) represents the equivalent impedance of the transmission line when the high-frequency is ω_{f}.

4. The line protection method for wind farm connected to flexible DC system according to claim 3, wherein the 1-mode action impedance Z_{act1,h}(ω_{f}) of the h-th sampling point at the high-frequency frequency of ω_{f} is expressed as:
$${Z}_{act , 1 , h} ( {ω}_{f} ) = \frac{{U}_{M 1 , h} ( {ω}_{f} )}{{I}_{M 1 , h} ( {ω}_{f} )} + \frac{{U}_{N 1 , h} ( {ω}_{f} )}{{I}_{N 1 , h} ( {ω}_{f} )}$$
where, U_{M1,h}(ω_{f}) and I_{M1,h}(ω_{f}) respectively represent the 1-mode voltage high-frequency component and the 1-mode current high-frequency component of the h-th sampling point when the high-frequency is ω_{f} at wind farm side protection installation of the transmission line, U_{N1,h}(ω_{f}) and I_{N1,h}(ω_{f}) respectively represent the 1-mode voltage high-frequency component and the 1-mode current high-frequency component of the h-th sampling point when the high-frequency is ω_{f} at flexible DC side protection installation of the transmission line.

5. The line protection method for wind farm connected to flexible DC system according to claim 3, wherein the fault identification criterion comprises:
S_{act}(ω_{f})≥Sₛₑₜ(ω_{f})
where, Sₛₑₜ(ω_{f}) represents the threshold value of the 1-mode transient action impedance difference of the transmission line when the high-frequency is ω_{f};
if S_{act}(ω_{f}) satisfies the fault identification criterion, it is judged to be a fault inside the area of the transmission line; otherwise, it is judged to be a fault outside the area of the transmission line.

6. The line protection method for wind farm connected to flexible DC system according to claim 5, wherein the threshold value Sₛₑₜ(ω_{f}) of the 1-mode transient action impedance difference of the transmission line when the high-frequency is m satisfies:
S_{actmin}^{out}(ω_{f})<Sₛₑₜ(ω_{f})<S_{actmax}ⁱⁿ(ω_{f})
where, S_{actmax}ⁱⁿ(ω_{f}) represents the maximum value of the fault inside the area of the transmission line when the high-frequency is ω_{f}, and S_{actmin}^{out}(ω_{f}) represents the minimum value of the fault outside the area of transmission line when the high-frequency is ω_{f}.

7. The line protection method for wind farm connected to flexible DC system according to claim 6, wherein the maximum value S_{actmax}ⁱⁿ(ω_{f}) of the fault inside the area of the transmission line at the high-frequency of w is expressed as:
$${S}_{act max}^{in} ( {ω}_{f} ) = {( {Z}_{fc} ( {ω}_{f} ) + {Z}_{mmc 1} ( {ω}_{f} ) + {Z}_{L} ( {ω}_{f} ) - {Z}_{fc} ( {ω}_{f} ) \frac{{i}_{fc 1} ( {ω}_{f} )}{{i}_{M 1} ( {ω}_{f} )} - \frac{{u}_{mmc 1} ( {ω}_{f} )}{{i}_{N 1} ( {ω}_{f} )} )}^{2}$$
where, Z_{fc(}ω_{f}) represents the equivalent impedance of the wind field side at the high-frequency of ω_{f}, Z_{mmc1}(ω_{f}) represents the 1-mode equivalent impedance of the flexible DC side at the high-frequency of ω_{f}, i_{fc1}(ω_{f}) represents the 1-mode equivalent transient current source of the wind field side at the high-frequency of ω_{f}, u_{mmc1}(ω_{f}) represents the 1-mode transient voltage source of the flexible DC side at the high-frequency of ω_{f}, i_{M1}(ω_{f}) represents the 1-mode current high frequency component of the wind field side protection installation of the transmission line at any sampling time when the high-frequency is ω_{f}, i_{N1}(ω_{f}) represents the 1-mode current high frequency component of the flexible DC side protection installation of the transmission line at any sampling time when the high-frequency is ω_{f};
the minimum value S_{actmin}^{out}(ω_{f}) of the fault outside the area of the transmission line at the high-frequency of ω_{f} is expressed as:
S_{actmin}^{out}(ω_{f})=Z_{L}²(ω_{f}).

8. The line protection method for wind farm connected to flexible DC system according to claim 5, wherein the high-frequency ω_{f} is ωₘₐₓ, and ωₘₐₓ is determined by the following way:
$${ω}_{max} = max \{ {ω}_{1} , {ω}_{2} , … , {ω}_{6} \}$$
where, ω₁˜ω₆ are the frequency solutions for the derivative of the 1-mode action impedance difference of the transmission line equal to 0, respectively, and max{ }represents the maximum value.

9. The line protection method for wind farm connected to flexible DC system according to claim 8, wherein the 1-mode action impedance difference ΔZ_{act1}(ω_{f}) of the transmission line is expressed as:
$$Δ {Z}_{act 1} ( {ω}_{f} ) = \frac{{A}_{7} {ω}_{f}^{7} + {A}_{5} {ω}_{f}^{5} + {A}_{3} {ω}_{f}^{3} + {A}_{1} {ω}_{f}}{{B}_{6} {ω}_{f}^{6} + {B}_{4} {ω}_{f}^{4} + {B}_{2} {ω}_{f}^{2} + {B}_{0}}$$
where, A₇, A₅, A₃, A₁, B₆, B₄, B₂, B₀ are constants calculated according to the fault transient model on both sides of the transmission line.

10. A line protection system for wind farm connected to flexible DC system, comprising:
a data acquisition module, configured to obtain high-frequency components of voltage and current at protection installations on both sides of a transmission line when fault of the transmission line of direct-drive wind field connected to the flexible DC system is monitored;
a 1-mode transient action impedance difference acquisition module, configured to obtain the 1-mode transient action impedance difference of the transmission line based on the high-frequency components of the voltage and current at the protection installations on both sides of the transmission line;
a fault identification and protection startup module, configured to determine whether a fault inside the area of the transmission line occurs based on the 1-mode transient action impedance difference and the fault identification criterion of the transmission line, and to start the protection action of the transmission line if it is determined that the fault inside the area of the transmission line occurs.
